(19) United States
(12) Patent Application Publication
(10) Pub. No.: US 2022/0271196 A1
(43) Pub. Date: Aug. 25, 2022

(54) Component with Buried Doped Areas and Procedures for the Production of A Component

(71) Applicant: OSRAM Opto Semiconductors GmbH, Regensburg (DE)

(72) Inventor: Siegfried Herrmann, Neukirchen (DE)

(21) Appl. No.: 17/611,041

(22) PCT Filed: May 14, 2020
(86) PCT No.: PCT/EP2020/063480

§ 371 Date: Nov. 12, 2021

(30) Foreign Application Priority Data
May 15, 2019 (DE) 10 2019 112 762.9

(51) Int. Cl. H01L 33/14; H01L 33/00; H01L 33/02; H01L 33/08; H01L 33/24; H01L 33/38

(52) U.S. Cl. CPC H01L 33/14; H01L 33/005; H01L 33/025; H01L 33/08; H01L 33/24; H01L 33/382; H01L 2933/0016; H01L 2933/0091

(57) ABSTRACT

In an embodiment, a component includes a carrier and a main body disposed on the carrier, wherein the main body includes a first semiconductor layer of a first charge carrier type, a second semiconductor layer of a second charge carrier type, and an optically active zone located therebetween, the optically active zone configured to emit radiation, wherein the first semiconductor layer includes a contiguous main layer and local regions at least locally buried in the main layer and laterally enclosed by the main layer, wherein the local regions are doped, and wherein the local regions has a smaller vertical layer thickness compared to the first semiconductor layer.

This patent application is a national phase filing under section 371 of PCT/EP2020/063480, filed May 14, 2020, which claims the priority of German patent application 102019112762.9, filed May 15, 2019, each of which is incorporated herein by reference in its entirety.

### TECHNICAL FIELD

A component is specified, in particular a component having buried doped regions. Furthermore, a method for producing a component is specified.

### BACKGROUND

LED semiconductor chips operated in a critical range, in particular high-current LED semiconductor chips often suffer from inhomogeneity with regard to the current distribution within the semiconductor layers, which results in luminance which is not distributed homogeneously. However, if the semiconductor layers are high-doped to increase the electrical conductivity, the efficiency with respect to light extraction decreases, since the light absorption of the semiconductor layers increases accordingly with increasing doping concentration.

### SUMMARY

Embodiments provide a component having improved electrical properties and improved optical properties. Further embodiments provide a method for producing a component having increased efficiency using a simplified and cost-efficient process.

According to at least one embodiment of a component, it comprises a carrier and a main body disposed on the carrier. The carrier may be a growth substrate on which the main body or a semiconductor body of the main body is epitaxially grown. For example, the semiconductor body or the main body is based on a compound semiconductor material, for instance a III-V or a II-VI compound semiconductor material. The carrier may be sapphire substrate or a semiconductor substrate. Deviating from this, it is possible that the carrier is different from a growth substrate. For example, the carrier is configured to electrically connect the main body. In particular, the carrier may comprise metallic layers or metallic conductive tracks electrically connected to the main body. For example, the carrier may be a printed circuit board.

According to at least one embodiment of the component, the main body comprises a first semiconductor layer of a first type of charge carrier and a second semiconductor layer of a second type of charge carrier different from the first type of charge carrier. For example, the first semiconductor layer and the second semiconductor layer are form to be of n-type and p-type, respectively, or vice versa. In particular, the main body has an optically active zone disposed between the first semiconductor layer and the second semiconductor layer. For example, the optically active zone is a pn-junction zone or a zone having a multiple quantum well structure. In operation of the component, the optically active zone is particularly configured to emit or detect electromagnetic radiation in the visible, ultraviolet or infrared spectral regions. In particular, the component or the main body of the component comprises a diode structure. For example, the component is a light-emitting diode, for instance a so-called micro-LED.

The first semiconductor layer and the second semiconductor layer may each have a plurality of sublayers arranged above each other along a vertical direction. For example, the sublayers of the first semiconductor layer and/or the sublayers of the second semiconductor layer or of all semiconductor layers of the main body are based on the same compound semiconductor material.

A plurality of layers or sub-layers are based on the same III-V compound semiconductor material if they have a same element from the third main group and a same element from the fifth main group of the periodic table of the elements. Similarly, the layers are based on the same II-VI compound semiconductor material if they have a same element from the second main group and a same element from the sixth main group of the periodic table of elements. The compound semiconductor material itself may be from a group of binary, ternary or quaternary compounds and may comprise dopants and additional elements. For example, the first semiconductor layer and the second semiconductor layer are each based on GaN. In this case, the sublayers of the first and/or second semiconductor layers may be formed of intrinsic or n-doped or p-doped GaN, GaAlN, InGaAlN layers.

A vertical direction is generally understood to be a direction perpendicular to a main extension surface of the carrier or of the main body. A lateral direction, on the other hand, is understood to be a direction directed in particular parallel to the main extension surface of the carrier or of the main body. The vertical direction and the lateral direction are transverse, for instance orthogonal to each other.

According to at least one embodiment of the component, the first semiconductor layer has a plurality of local regions which are doped. The local doped regions are in particular individual regions of the first semiconductor layer which are spatially spaced apart from one another in lateral directions. Between the laterally spaced doped regions, there are in particular further regions of the first semiconductor layer which are, for example, not doped or have a different doping concentration compared to the local doped regions. Within the producing tolerances, a single, local and doped region of the first semiconductor layer is in particular a closed region of the semiconductor layer with the same doping concentration.

According to at least one embodiment of the component, the first semiconductor layer comprises a main layer. In particular, the main layer is formed contiguously and is for instance directly adjacent to the local regions, for example to all local regions of the first semiconductor layer. The main layer is arranged at least in places in the vertical direction between the optically active zone and the local regions of the first semiconductor layer. The main layer may be formed by a single layer, a layer sequence or a plurality of sub-layers.

In particular, the local regions are at least partially or completely buried in the main layer. In the lateral directions, the local regions may be enclosed, in particular completely enclosed, by the main layer. In a plan view of the carrier, the local regions may be completely covered by the main layer. In particular, the local regions have lateral surfaces and surfaces facing the active zone which are partially or completely covered by the main layer. In particular, the local regions are mechanically connected to each other by the material of the main layer. It is possible that the local regions have surfaces facing away from the active zone which are free from being covered by the material of the main layer. Along a vertical direction, the local regions and the main layer may be flush. However, if the local regions are fully buried or embedded in the main layer, the local regions will have no locations that are not covered by the main layer.

In particular, the local regions differ from the main layer at least in that the local regions and the main layer are doped differently, i.e. have different dopants, and/or have different doping concentrations. However, the local regions and the main layer may be based on the same compound semiconductor material, for example on GaN, GaP or GaAs. In particular, due to the different dopants and/or doping concentrations, the main layer and the local regions of the first semiconductor layer may have different electrical and optical properties. By specific designs of the local regions of the first semiconductor layer, the current distribution, the light injection and/or the light extraction of the component can be improved.

For example, those local regions which are primarily configured for current distribution within the first semiconductor layer may be higher-doped compared to their surroundings. In particular, these local regions form current distribution bridges with a reduced electrical resistance within the first semiconductor layer. Those local regions which are configured for generating and transmitting electromagnetic radiation, for example for out-coupling electromagnetic radiation, may be lower-doped compared to their surroundings. Compared to their surroundings, these local regions have a lower absorption coefficient and thus form optically favored windows of the first semiconductor layer through which electromagnetic radiation can be transmitted without significant losses.

Depending on the application, it is conceivable that the first semiconductor layer has, in addition to the main layer, either local high-doped regions or local low doped regions. For example, if the main layer has a higher doping concentration than the local regions, the main layer can form a system of current distribution bridges, in particular of interconnected current distribution bridges, wherein the local regions serve as optically favored windows of the first semiconductor layer. Conversely, if the main layer has a lower dopant concentration than the local regions, the main layer may serve as an optically favored window of the first semiconductor layer, wherein the local doped regions form the current distribution bridges within the first semiconductor layer. It is also possible for the semiconductor layer to have both local high-doped regions and local low doped regions in addition to the main layer. The main layer may be doped or intrinsic.

In at least one embodiment, the component comprises a carrier and a main body disposed on the carrier. The main body comprises a first semiconductor layer of a first charge carrier type, a second semiconductor layer of a second charge carrier type, and an optically active zone located therebetween. The first semiconductor layer has a contiguous main layer and local regions, wherein the local regions are buried at least in places in the main layer and laterally enclosed by the main layer. The local regions are preferably doped and thus configured for adjusting local electrical and local optical properties of the first semiconductor layer. In particular, the local regions have a smaller vertical layer thickness compared to the first semiconductor layer. The local regions are thus at least partially buried in particular in the first semiconductor layer.

According to at least one embodiment of the component, the local regions are individual laterally spaced regions of the first semiconductor layer. The main layer is arranged in the vertical direction at least partially between the active zone and the local regions. The local regions may have the same material composition. Within producing tolerances, the local regions may have the same or different doping concentrations. The local regions, in particular all of the local regions, may have a higher or a lower dopant concentration than the main layer. However, it is possible that some of the local regions have a higher dopant concentration than the main layer, while other local regions have a lower dopant concentration than the main layer.

According to at least one embodiment of the component, the local regions and the main layer are based on the same semiconductor material. In particular, the main layer has a larger maximum vertical layer thickness than the local regions. In other words, the local regions have a maximum vertical layer thickness that is smaller than the maximum vertical layer thickness of the main layer. For example, the local regions are spatially spaced apart from each other in lateral directions by intermediate regions, the intermediate regions being filled, in particular completely filled, by material of the main layer. In top view, the main layer covers the local regions in particular completely. The local regions thus have in particular a smaller maximum and in particular also a smaller average vertical layer thickness than the main layer.

According to at least one embodiment of the component, the main layer of the first semiconductor layer has a first doping concentration. Preferably, the local regions have a doping concentration that differs from the first doping concentration of the main layer by at least 5%, 10%, 50%, 100% or by 1000%.

In case of doubt, a dopant concentration of a layer or a region is understood as the average dopant concentration of this layer or region. If the main layer is low-doped or the main layer has only traces of dopants, a ratio of the dopant concentration of the local regions to the dopant concentration of the main layer may be at least 10, 10², 10³, 10⁴, 10⁵ or at least 10⁶. In contrast, if the main layer is high-doped and the local regions are low-doped, a ratio of the doping concentration of the main layer to the doping concentration of the local regions may be at least 10, 10², 10³, 10⁴, 10⁵ or at least 10⁶.

According to at least one embodiment of the component, the first semiconductor layer is n-type. The main layer may have a maximum doping concentration or an actual doping concentration between 4·10¹⁸ cm⁻³ and 4·10¹⁹ cm⁻³ inclusive.

The n-doped local regions are preferably implemented in places as current distribution bridges, which have a lower electrical resistance than the main layer. This may be achieved by a dopant concentration of the current distribution bridges being greater than the dopant concentration of the main layer by at least 5%, 10%, 50%, 100% or by at least 1000%. The main layer and the local regions may have the same dopants.

Alternatively or additionally, it is possible that the local n-doped regions are implemented in places as optically favored windows which have a greater transmittance than the main layer for radiation emitted by the optically active zone during operation of the component. This can be achieved by the optically favored windows having a doping concentration that is smaller than the doping concentration of the main layer by at least 5%, 10%, 50%, 100% or by at least 1000%.

It is possible for the local regions to have different doping concentrations. For example, some of the local regions may be implemented as current distribution bridges. Other local regions may be formed as optically favored windows of the first semiconductor layer.

According to at least one embodiment of the component, the doping concentration of the main layer, in particular the average doping concentration or the actual doping concentration of the main layer, is between 1·10¹⁷ cm⁻³ and 4·10¹⁹ cm⁻³ inclusive or between 4·10¹⁸ cm⁻³ and 4·10¹⁹ cm⁻³ inclusive. Deviating therefrom, it is possible that the main layer has a lower dopant concentration or only traces of dopants that have diffused into the main layer, for instance from the local doped regions.

According to at least one embodiment of the component,

the first semiconductor layer is p-type. The main layer may have a maximum doping concentration or an actual doping concentration between 1·10¹⁷ cm⁻³ and 3·10¹⁸ cm⁻³ inclusive.

The p-doped local regions are preferably implemented in places as current distribution bridges, which have a lower electrical resistance than the main layer. This may be achieved by having a dopant concentration of the current distribution bridges greater than the dopant concentration of the main layer by at least 5%, 10%, 50%, 100% or by at least 1000%. The main layer and the local regions may have the same dopants.

Alternatively or additionally, it is possible that the p-doped local regions are implemented in places as optically favored windows which have a greater transmittance than the main layer for radiation emitted by the optically active zone during operation of the component. This can be achieved by the optically favored windows having a doping concentration that is smaller than the doping concentration of the main layer by at least 5%, 10%, 50%, 100% or by at least 1000%.

According to at least one embodiment of the component, the second semiconductor layer has a contiguous main layer and local regions, wherein the local regions are buried at least in places in the main layer of the second semiconductor layer and are laterally enclosed by the main layer of the second semiconductor layer. The local regions are preferably doped and thus configured for adjusting local electrical and local optical properties of the second semiconductor layer. In particular, the local regions have a smaller vertical layer thickness compared to the second semiconductor layer.

Analogous to the first semiconductor layer, it is possible that the second semiconductor layer also has local regions having different doping concentrations, wherein the local regions of the second semiconductor layer are formed as current distribution bridges or optically favored windows of the second semiconductor layer. It is also possible that some of the local regions are formed as current distribution bridges and other local regions are formed as optically favored windows of the second semiconductor layer.

The second semiconductor layer may be formed analogously to the first semiconductor layer with respect to the main layer and the local doped regions. The features specified in connection with the first semiconductor layer, in particular with respect to the main layer, the local regions, the different dopants and/or dopant concentrations in the main layer and in the local regions, can therefore be used for the second semiconductor layer.

According to at least one embodiment of the component, the local regions of the first and/or of the second semiconductor layer are implemented in places as current distribution bridges and in places as optically favored windows, wherein the current distribution bridges have a higher doping concentration than the optically favored windows. For example, the current distribution bridges have a dopant concentration that differs by at least 5%, 10%, 50%, 100%, or 1000% from the dopant concentration of the optically favored windows. It is possible that some of the local regions, implemented as current distribution bridges, are high-doped, while other local regions, implemented as optically favored windows, are low-doped, such that a ratio of the doping concentration of the high-doped regions to the doping concentration of the low-doped regions may also be at least 10, 10², 10³, 10⁴, 10⁵ or at least 10⁶ for example between 10 and 10¹⁶ inclusive.

According to at least one embodiment of the component, it has a plurality of laterally spaced through-vias, wherein the through-vias extend throughout the second semiconductor layer and the active zone into the first semiconductor layer for electrically contacting the first semiconductor layer. In a top view of the carrier, at least some of the through-vias may overlap with local regions configured as current distribution bridges. In top view, the current extension ridges may be configured to extend laterally away from the associated through-via or through-vias. It is also possible that several current distribution bridges meet at a through-via.

According to at least one embodiment of the component, the through-vias and the local regions configured as optically favored windows are free of overlaps when viewed from above onto the carrier. It is possible that a plurality of through-vias and/or a plurality of local regions configured as current distribution bridges are arranged around a local region configured as an optically favored window in such a way that the latter is surrounded in lateral directions by the through-vias and/or by the current distribution bridges.

According to at least one embodiment of the component, the buried regions are epitaxially formed semiconductor regions. The buried regions of the first semiconductor layer or the second semiconductor layer may be formed of the same material. However, it is possible that different local buried regions may have different doping concentrations and/or different dopants.

According to at least one embodiment of the component, the latter has a contact point for externally electrically contacting the component. The local regions are implemented in places as current distribution bridges. Preferably, the current distribution bridges have a gradient with respect to their doping concentration, so that the current distribution bridges having a first lateral distance from the contact point have a higher doping concentration than the current distribution bridges having a second lateral distance from the contact point, wherein the first distance is smaller than the second distance. By such a design of the doping concentrations, the first or the second semiconductor layer has regions of reduced electrical resistance with increasing proximity to the contact point, so that electrical charge carriers can be better dissipated from the contact point and thus uniformly distributed in the first or second semiconductor layer.

According to at least one embodiment of the component, the optically active zone has an inner vertical step in the main body. In particular, the first semiconductor layer and the second semiconductor layer each have a corresponding vertical jump at the step of the active zone. The active zone may have at least two sub-regions that are mechanically connected but vertically offset from each other. The vertical offset within the active zone may lead to a so-called Purcell effect, wherein the probability of spontaneous emission and thus the emission rate may be increased.

The vertical jump may be an abrupt change or may be caused by a gradual change in the layer structure of the semiconductor body or of the main body. The vertical jump or step may have a transition region, for example, in the form of a horizontal contiguous flattening region. It is possible that the vertical jump or the vertical step of the active zone contiguously transitions to layers above or below it, in particular planar layers, so that vertical jump or the vertical step is flattened in the further semiconductor layers. In particular, the edges of the step may be flattened or rounded. However, it is possible that the step or vertical jump is formed not only in the active zone but also in further layers of the semiconductor body. For example, the step or vertical jump may also be found in the quantum well structure.

According to at least one embodiment of the component, it has out-coupling structures for increasing the out-coupling efficiency of electromagnetic radiation, wherein the out-coupling structures is located in places on the main body and/or within the main body. The outer out-coupling structures may be formed by patterning an outer semiconductor layer. The inner out-coupling structures may be formed by using a patterned growth substrate. In particular, a patterned growth substrate has an exposed growth surface to which semiconductor material can be directly deposited to form the main body. Such a growth substrate may be a patterned sapphire substrate.

In one embodiment of a light source, it comprises a component, in particular a component described herein, wherein in operation of the component, the optically active zone is configured to generate electromagnetic radiation in the visible, infrared or ultraviolet spectral range. The light source may be used in general lighting or in a headlight of a motor vehicle. It is also conceivable that the light source or the component may find application in electronic components, mobile phones, touchpads, laser printers, cameras, recognition cameras, displays or in systems comprising LEDs, sensors, laser diodes and/or detectors. The component may be a high current mode LED. It is also possible that the component may be a low current mode LED, in particular a sapphire LED, for instance in the form of a flip chip. Further, the component may be a solid state component, for instance a solid state LED or a solid state laser.

In at least one embodiment of a method for producing a component, a plurality of laterally spaced and doped regions of a semiconductor material are formed on a growth substrate. The main body of the component to be produced comprises a first semiconductor layer of a first carrier type, a second semiconductor layer of a second carrier type and an optically active zone located therebetween. After the doped regions are formed on the growth substrate, the doped regions are overgrown with semiconductor materials to form the main body, in particular, such that the doped regions are formed as integral subregions of the first semiconductor layer. The first semiconductor layer further comprises a contiguous main layer, wherein the doped regions are buried at least in places in the main layer and laterally enclosed by the main layer. In particular, the doped regions are configured for adjusting local electrical and local optical properties of the first semiconductor layer. In this case, the local regions have a smaller vertical layer thickness compared to the first semiconductor layer.

According to at least one embodiment of the method for producing a component, a plurality of laterally spaced through-vias for electrically contacting the first semiconductor layer are formed such that the through-vias extend throughout the second semiconductor layer and the active zone into the first semiconductor layer. The through-vias are formed preferably in an aligned manner with respect to the local buried doped regions. The positions of the through-vias may be predetermined by the positions of the local doped regions. For example, in top view, the through-vias have overlaps with the higher-doped regions and do not have overlaps with the lower-doped regions of the first and/or of the second semiconductor layer.

According to at least one embodiment of the method, the main body is first formed as part of a main body composite, wherein the main body is separated from the main body composite such that the main body is adjusted to the shape of a local doped region or to the shape or to an arrangement of multiple local doped regions. For example, the main body and at least one local doped region of the first or second semiconductor layer may have the same geometry. In this sense, the main body may be formed congruently with the local doped region. Such a congruent geometry of the main body and the local doped region, or an adjustment of the main body to the geometry or to the arrangement of the local doped regions, may be observed on the finished component. In particular, the doped regions are epitaxially integrated in the main body. For instance, the doped regions are geometrically correlated with the structures of the component, in particular with the chip structures.

According to at least one embodiment of the method, homogeneous layers, in particular contiguous layers, are first grown to form the local doped regions. Subsequently, a mask structure, for example a SiN mask, can be applied to these layers. The mask structure can be used to perform a regional diffusion of dopants, in particular in the epitaxial reactor, to increase the local n- or p-dopant concentration. The mask structure can be removed before further semiconductor layers, in particular those comprising the active zone, are deposited on the local doped regions. As an alternative to the local diffusion of dopants, it is possible to form the local doped regions with increased local n- or p-dopant concentration by regionally growing geometric layer structures, in particular in the epitaxial reactor. A mask structure can also be used for this purpose, which is removed before further semiconductor layers are deposited, in particular those comprising the active zone, on the local doped regions.

### BRIEF DESCRIPTION OF THE DRAWINGS

Further embodiments and further developments of the component or the method will be apparent from the embodiments explained below in connection with FIGS. 1A to 10.

FIGS. 1A, 1B, and 1C show schematic illustrations of various comparative examples of a component;

FIGS. 2A, 2B, 2C, 2D, and 2E show schematic illustrations of an embodiment of a component;

FIGS. 3A, 3B, 4A and 4B show schematic illustrations of a further embodiment of a component;

FIGS. 5A, 5B, and 5C show schematic illustrations explaining the basic principle of a component described herein;

FIGS. 6A, 6B, 6C, 7A and 7B show schematic illustrations of some method steps of an embodiment for producing a component;

FIGS. 8A and 8B show schematic representations of some curves with respect to the doping concentration or curves depending on the different doping concentrations; and

FIGS. 9A, 9B, 9C and 10 show schematic representations of further examples of embodiments of a component.

### DETAILED DESCRIPTION OF ILLUSTRATIVE EMBODIMENTS

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

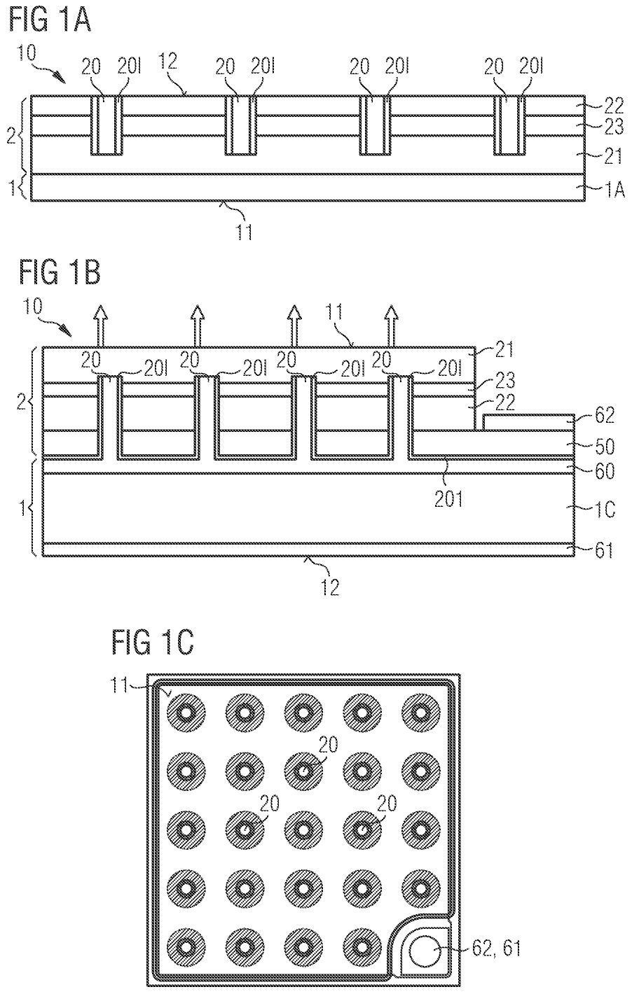

Referring to FIG. 1A, a comparative example of a component 10 is schematically shown, which comprises a carrier 1 and a main body 2 disposed on the carrier 1. The main body 2 may be a semiconductor body 2. In particular, the carrier 1 is a growth substrate 1A on which the semiconductor body 2 is epitaxially grown. It is possible that the carrier 1 is formed to be radiation-transmissive. The carrier 1 may be a sapphire substrate 1A or a semiconductor substrate 1A. The component 10 has a front side 11 and a rear side 12 opposite to the front side 11. For example, the front side 11 is formed as a radiation exit side or a radiation entrance side of the component 10. It is possible that the component 10 is externally electrically contactable via the rear side 12, in particular exclusively via the rear side 12.

The main body 2 comprises a first semiconductor layer 21, a second semiconductor layer 22 and an optically active zone 23 arranged between the first semiconductor layer 21 and the second semiconductor layer 22. In operation of the component 10, the active zone 23 is particularly configured for generating or detecting electromagnetic radiation. Preferably, the first semiconductor layer 21 is n-type. In this case, the second semiconductor layer 22 is p-type. However, it is also possible that the first semiconductor layer 21 is p-type and the first semiconductor layer 22 is n-type.

For electrically contacting the main body 2 or the component 10, the component 10 has a plurality of through-vias 20. The through-vias 20 extend along the vertical direction, in particular throughout the second semiconductor layer 22 and the optically active zone 23 into the first semiconductor layer 21. The through-via 20 is enclosed in lateral directions by an insulating structure 20I. The insulating structure 20I prevents direct electrical contact between the through-via 20 and the second semiconductor layer 22, and between the through-via 20 and the optically active zone 23. The insulating structure 20I extends along the vertical direction analogously to the through-via 20 throughout the second semiconductor layer 22 and the optically active zone 23 into the first semiconductor layer 21. In particular, the through-via 20 is in direct electrical contact with the first semiconductor layer 21. For electrically contacting the second semiconductor layer 22, the component 10 may have an electrical contact point on the second semiconductor layer 22 which is not shown in FIG. 1A.

The exemplary embodiment of a component 10 shown in FIG. 1B is substantially the same as the component 10 shown in FIG. 1A, except that the component 10 has a carrier 1 that is different from a growth substrate. For example, the carrier 1 comprises a base body 1C made of metal, ceramic or plastic. Furthermore, the carrier 1 comprises a first connection layer 60 and a first contact layer 61 for electrically contacting the through-vias 20.

The through-vias 20, for instance all of the through-vias 20, may be electrically connected to each other via the first connection layer 60. For example, the first connection layer 60 may be externally electrically contactable via the contact layer 61. The first contact layer 61 may be arranged laterally to the connection layer 60 and have the form of a contact surface or a contact pad, or—as schematically shown in FIG. 1B—may be arranged on the rear side 12 of the component 10. The base body 1C of the carrier 1 may be electrically conductive. Alternatively, it is possible for the base body 1C of the carrier 1 to be electrically insulating, wherein through-contacts are formed throughout the base body 1C for establishing an electrical connection between the connection layer 60 and the first contact layer 61.

For electrically contacting the second semiconductor layer 22, the component 10 comprises a second connection layer 50 arranged in the vertical direction between the second semiconductor layer 22 and the first connection layer 60. Referring to FIG. 1B, the first connection layer 60 and the second connection layer 50 are arranged on the same side of the main body 2, with through-vias 20 extending through the second connection layer 50.

The second connection layer 50 is electrically insulated from the first connection layer 60 and from the through-vias 20 by the insulating structure 20I, which is disposed regionally between the first connection layer 60 and the second connection layer 50. It is possible that the second connection layer 50 is directly adjacent to the second semiconductor layer 22. For external electrical contacting of the second connection layer 50, the component 10 comprises a second contact layer 62. The second contact layer 62 may be arranged laterally to the semiconductor body 2 and may, in particular, have the form of a contact surface or a contact pad.

As a further difference from the component 10 shown in FIG. 1A, the component 10 shown in FIG. 1B is void of a growth substrate 1A. In particular, the growth substrate 1A is removed, thereby exposing the first semiconductor layer 21. For example, the exposed surface of the first semiconductor layer 21 forms the front side 11 of the component 10.

In FIG. 1C, the component 10 is schematically shown in a top view of the front side 11. In operation of the component 10, the optically active zone 23 is configured in particular to generate electromagnetic radiation, wherein the front side 11 serves as the radiation exit surface of the component 10.

As shown schematically in FIG. 1C, an inhomogeneity in the luminance distribution may occur on the front side 11 of the component 10. The front side 11 may exhibit increased luminance in the immediate vicinity of the through-via(s) 20. As the lateral distance from the through-vias 20 increases, the luminance gradually decreases. This is due to the fact that the first semiconductor layer 21 generally has a low transverse electrical conductivity, and therefore the charge carriers are increasingly located in the immediate vicinity of the through-vias 20. In order to increase the electrical conductivity of the first semiconductor layer 21, the first semiconductor layer 21 may be highly doped. However, the high doping concentration in the first semiconductor layer 21 leads to an increased absorption of the electromagnetic radiation generated in the optically active zone 23.

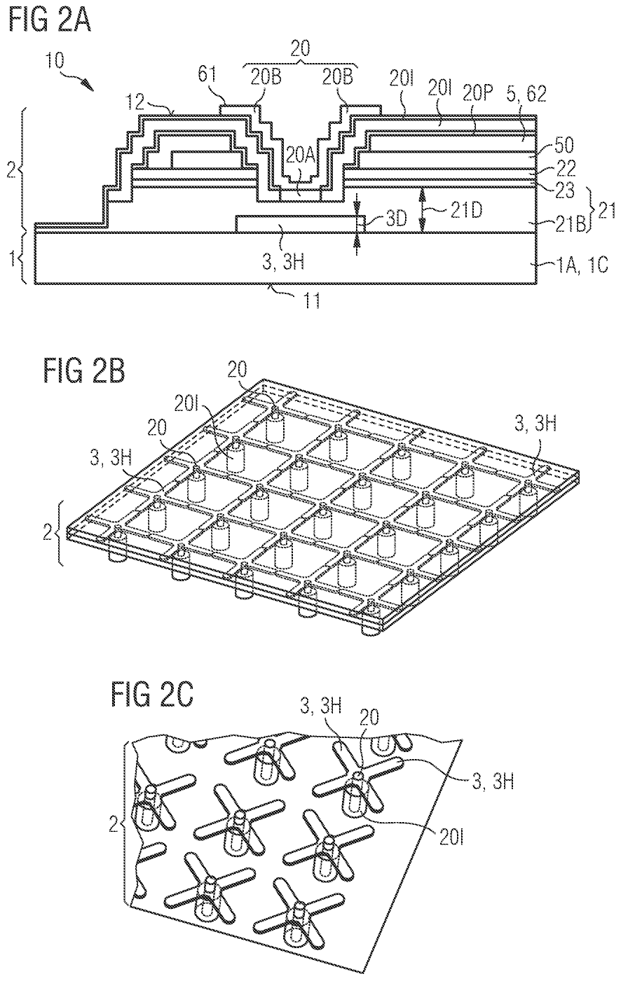

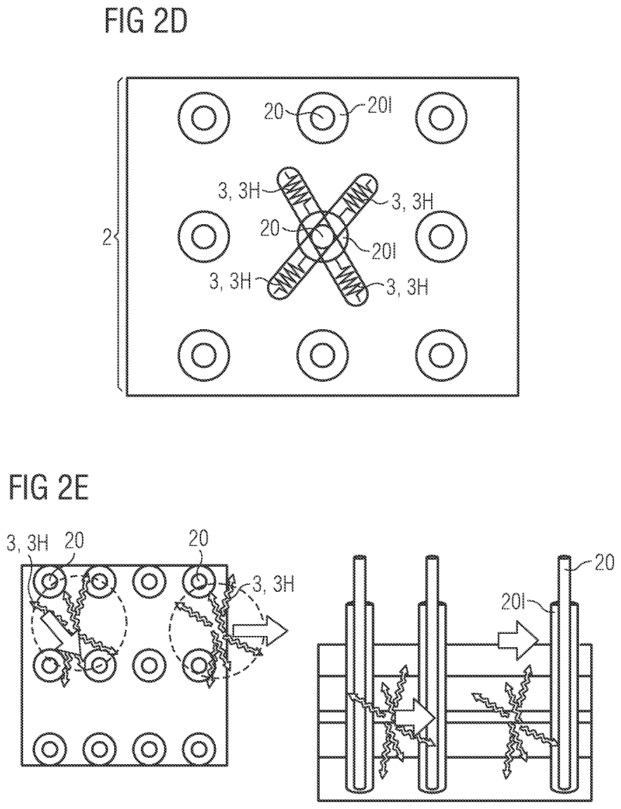

The exemplary embodiment shown in FIG. 2A is substantially the same as the exemplary embodiment of a component 10 shown in FIG. 1A, except that the layers of the component 10 are shown in slightly more detail. The carrier 1 may be a growth substrate 1A or may have a base body 1C different from the growth substrate 1A. As a further difference from FIG. 1A, the first semiconductor layer 21 shown in FIG. 2A has a main layer 21B and at least one local doped region 3. In terms of doping concentration, the local doped region 3 differs from the main layer 21B by, for example, at least 5%, 10%, 50%, 100% or 1000%. In this respect, the local doped region 3 may have a higher or a lower doping concentration than the main layer 21B.

In particular, the local doped region 3 is at least partially buried in the main layer 21B. The doped region 3 has a vertical layer thickness 3D that is smaller than a vertical layer thickness 21D of the main layer 21B or a vertical layer thickness 21D of the entire first semiconductor layer 21. For example, a ratio of the vertical layer thickness 21D to the vertical layer thickness 3D is between 1 and 10 inclusive, or between 1 and 5 inclusive, or between 1 and 3 inclusive. The vertical layer thickness 21D may be at least 1.5 times, twice, three times, or at least five times as large as the vertical layer thickness 3D. In a top view of the carrier 1, a surface facing the active zone 23 as well as all side surfaces of the doped region 3 may be covered, in particular completely covered, by the main layer 21B. It is possible that a surface of the doped region 3 facing away from the active zone 23 is free from being covered by the main layer 21B. At this surface, the doped region 3 may be flush with the main layer 21B. In particular, the first semiconductor layer 21 has a plurality of such local doped regions 3.

In FIG. 2A, it is schematically shown that the local region 3 is formed as a high-doped or higher-doped region 3H, which in particular has a higher concentration of dopants than the main layer 21B. In top view, the through-via 20 may overlap with its associated local higher-doped region 3H. The through-via 20 may comprise a connection layer 20A and a main layer 20B, wherein the connection layer 20A is in particular directly adjacent to the first semiconductor layer 21. The main layer 20B of the through-via 20 may partially or completely cover an opening of the main body 2, and is in particular in direct electrical contact with the connection layer 20A. Along the lateral direction, the doped region 3H may protrude beyond the through-via 20 or at least beyond the connection layer 20A of the through-via 20.

For electrical contacting of the second semiconductor layer 22, the component 10 has, for example, further connection layers 5 and 50 or at least one contact layer 62, a second connection layer 50 being in particular in direct electrical contact with the second semiconductor layer 22. The second connection layer 50 or the contact layer 62 may be formed as a mirror layer. For electrically insulating the through-via 20 from the active zone 23, the second semiconductor layer 22 and from the connection layers 5 and 50 as well as from the contact layer 62, the component 10 comprises an insulating structure 20I and/or a passivation layer 20P. The insulating structure 20I may be a single layer or a multilayer. The connection layer 20A of the through-via 20 may be completely surrounded by the insulating structure 20I in lateral directions.

The insulating structure 20I may cover, in particular completely cover, a side surface of the main body 2. At the side surface of the main body 2, the insulating structure 20I forms in particular a diffusion barrier preventing possible leakage currents via the chip edge during chip processing as well as during operation of the component 10.

In particular, the local higher-doped region 3H is formed as a current distribution bridge. In FIG. 2B, a plurality of such current distribution bridges are schematically shown. The current distribution bridges or the higher-doped regions 3H may be arranged in a star shape around the respective through-vias 20. In other words, the current distribution bridges may start from a through-via 20 in top view and may extend away from the through-via 20 along lateral directions. In particular, the current distribution bridge extends along the lateral direction from one through-vias 20 towards another through-vias 20. For example, the current distribution bridges are arranged such that adjacent through-vias 20 are connected to each other via the current distribution bridges. In top view, the current distribution bridges may form a network that promotes a uniform current density distribution within the first semiconductor layer 21. The network may include a plurality of rows and columns of current distribution bridges.

The exemplary embodiment shown in FIG. 2C is substantially the same as the exemplary embodiment of a component 10 shown in FIG. 2B. From each of the through-vias 20, the current distribution bridges extend in four different lateral directions. Unlike FIG. 2B, the current distribution bridges starting from different through-vias 20 do not contact each other.

In top view, the higher-doped regions 3H, in particular implemented as current distribution bridges, may cover a subregion of the surface of the first semiconductor layer 21 for instance between 3% and 40% inclusive, between 3% and 30% inclusive, between 3% and 20% inclusive, or between 3% and 10% inclusive.

FIGS. 2D and 2E schematically illustrate the higher-doped regions 3H formed as current distribution bridges and their influences in terms of increasing the transverse conductivity within the first semiconductor layer 21.

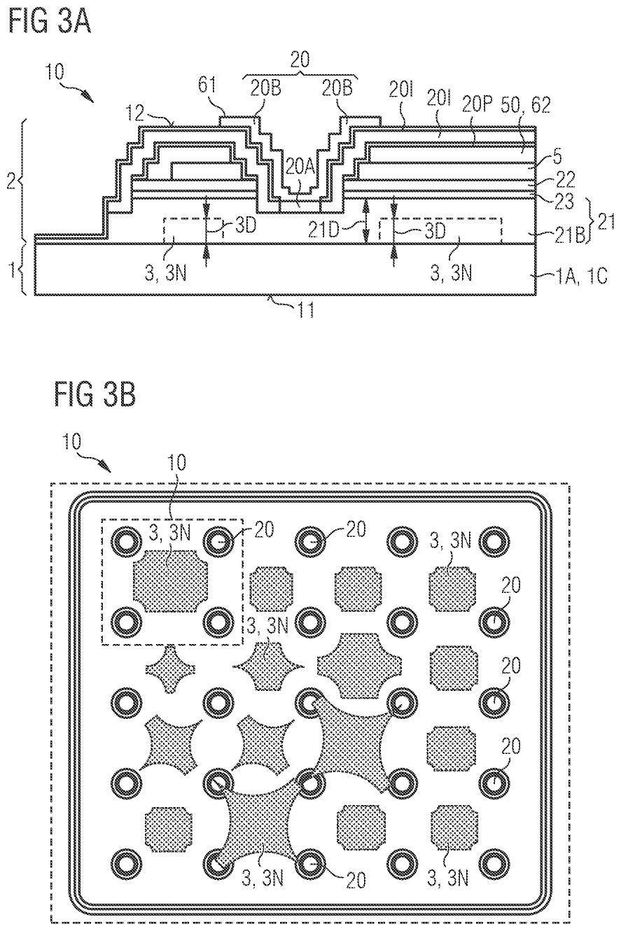

The exemplary embodiment illustrated in FIG. 3A essentially corresponds to the exemplary embodiment of a component 10 illustrated in FIG. 2A. In contrast thereto, the local doped regions 3 are formed in particular as low-doped or as lower-doped regions 3N. In particular, the local doped regions 3N are configured as optically favored windows of the first semiconductor layer 21. Preferably, the local doped regions 3N have a lower concentration of dopants and thus a lower absorption coefficient than the main layer 21B. In top view, the lower-doped regions 3N in particular have no or hardly have any overlaps with the associated through-vias 20 or with the connection layers 20A of the through-vias 20.

In top view, the lower-doped regions 3N may cover a subregion of the surface area of the first semiconductor layer 21 for instance between 20% and 90% inclusive, between 30% and 80% inclusive, between 40% and 70% inclusive, or between 30% and 60% inclusive.

In FIG. 3B, the lower-doped regions 3N, which are formed in particular as optically favored windows of the component 10, are shown schematically. In top view, the lower-doped regions 3N are arranged in lateral directions, in particular between the through-vias 20. Depending on the application, the component 10 may be divided into smaller components 10. For example, in FIG. 3B, a sub-region is marked which may form a single component 10. The single marked component 10 has an optically favored window 3N adapted to the geometry of this component 10. In this sense, congruent epitaxial structures or doped regions 3 adapted to the geometry of the component 10 may be generated.

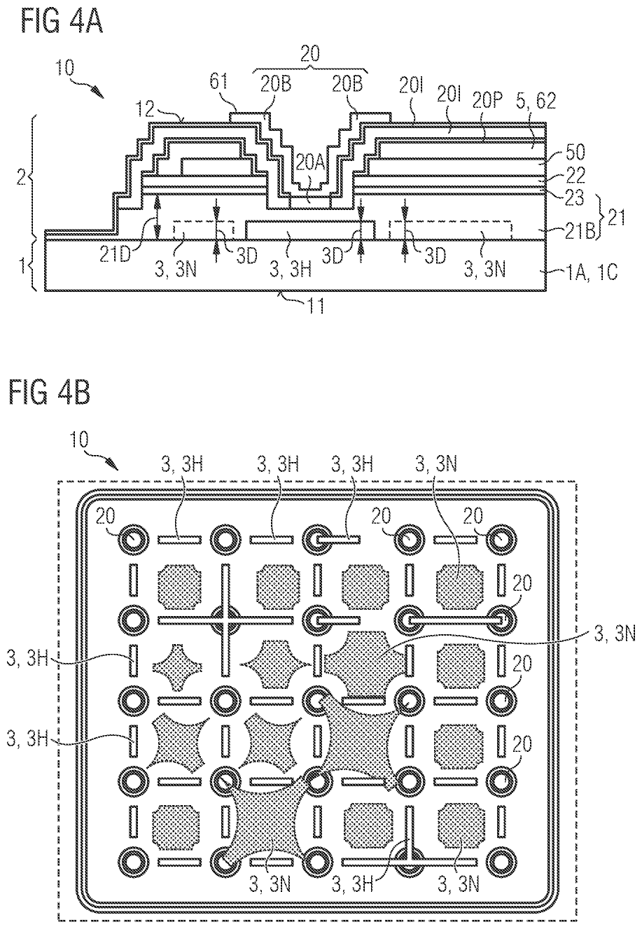

The exemplary embodiment illustrated in FIG. 4A is substantially the same as the exemplary embodiments of a component 10 illustrated in FIGS. 2A and 3A, except that the component 10 has both lower-doped regions 3N and higher-doped regions 3H. Therefore, the features described in connection with FIGS. 2A and 3A can also be applied to the exemplary embodiment illustrated in FIG. 4A. The regions 3H have a higher doping concentration than the regions 3N and/or than the main layer 21B.

FIG. 4B schematically shows a possible arrangement of the local doped regions 3. The higher-doped regions 3H, which are formed as current-distributing ridges, can each be formed in the form of strips. The lower-doped regions 3N, which are formed as optically favored windows, can be formed as individual regions which are surrounded in lateral directions by the higher-doped regions 3H.

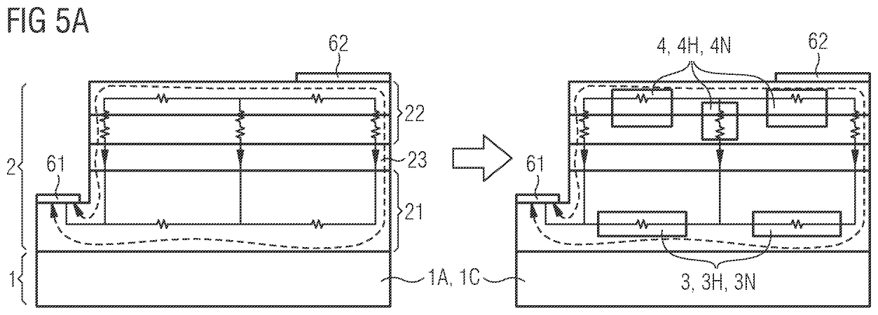

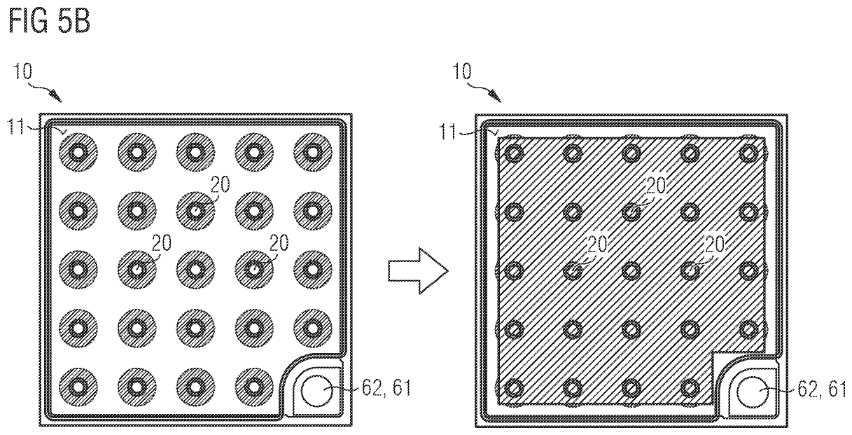

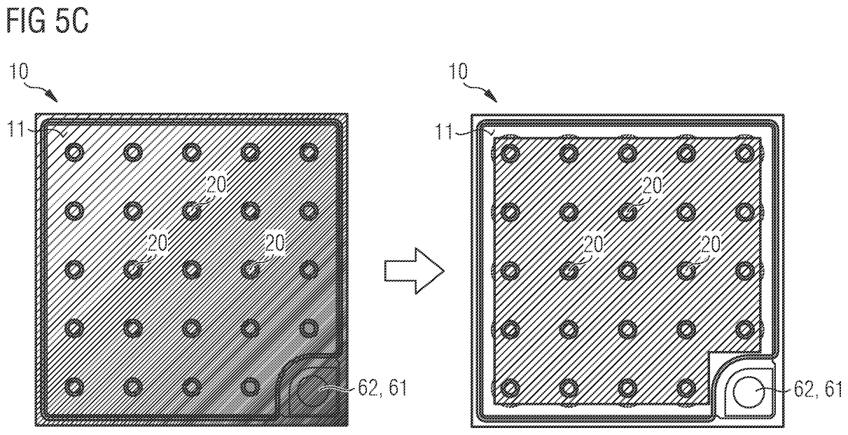

FIG. 5A schematically illustrates internal circuits in a component 10 without the local doped regions 3 and in a component 10 with the local doped regions 3. The component 10 has a lateral first contact point 61 on the first semiconductor layer 21 and a second contact point 62 on the second semiconductor layer 22. The component 10 may have through-vias 20 or be free of through-vias 20. Such a component 10 without the local doped regions 3 may have inhomogeneities in the current density distribution and thus in particular in the luminance distribution, which are schematically shown for example in FIGS. 5B and 5C on the left side, respectively.

By using the local doped regions 3, which are implemented in particular as current distribution bridges 3H or as optically favored windows 3N within the first semiconductor layer 21, a uniform current density distribution or a uniform luminance distribution can be achieved, which is schematically shown, for example, on the right side in FIGS. 5B and 5C, respectively. Higher operating currents are possible since the current density is homogeneously distributed over the chip surface. In particular, local hot spots in the immediate vicinity of the through-vias 20 can be avoided. If the component 10 has a laterally arranged contact point 61, the doped regions 3, in particular the more high-doped regions 3H, can be formed in such a way that they have a gradient with respect to the doping concentration, so that the doping concentration decreases in particular with increasing lateral distance from the laterally arranged contact point 61 (FIG. 5C).

In FIG. 5A, it is schematically shown that the second semiconductor layer 22 may have local doped regions 4 quite analogously to the first semiconductor layer 21. The local doped regions 4 may be higher-doped regions 4H and/or lower-doped regions 4N. The local regions 4 of the second semiconductor layer 22 may be formed quite analogously to the local regions 3 of the first semiconductor layer 21. The features described in connection with the local regions 3, for example, with respect to the position, the design, the layer thickness and/or the doping, can therefore be used analogously for the local regions 4 of the second semiconductor layer 22.

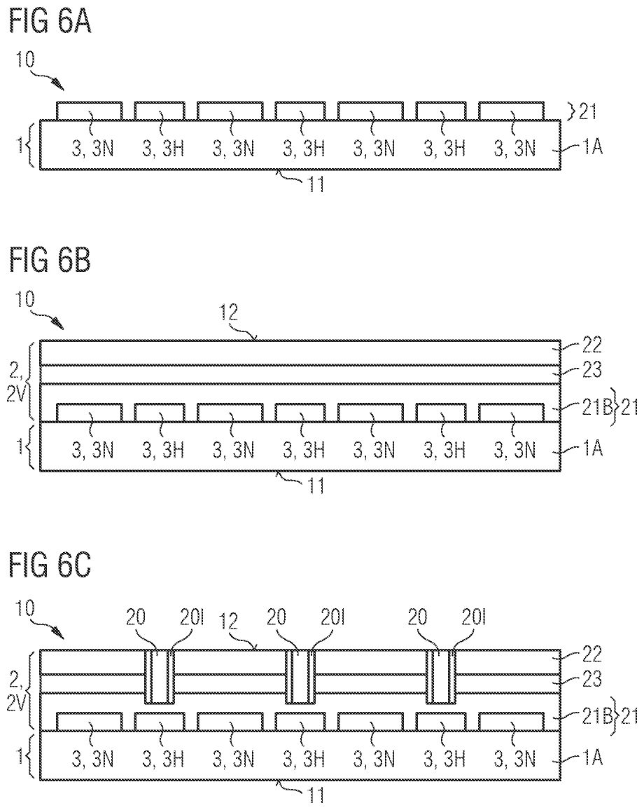

FIGS. 6A, 6B and 6C schematically illustrate some method steps for producing a component 10 described in particular herein. The features described in connection with the component 10 can therefore also be used for the method, and vice versa.

Referring to FIG. 6A, a growth substrate 1A is provided. A plurality of laterally spaced and doped regions 3 are formed on the growth substrate 1A. Referring to FIG. 6A, the doped regions 3 are shown to comprise higher-doped regions 3H and lower-doped regions 3N. However, it is possible that the doped regions 3 are exclusively higher-doped regions 3H or exclusively lower-doped regions 3N.

Regions on the growth substrate 1A may be patterned photo-lithographically to form the doped regions 3. For example, a mask may be formed, in particular formed of a photostructurable material. Epitaxial semiconductor layers are grown in the patterned regions to form the laterally spaced and doped regions 3. Alternatively, it is possible that the semiconductor layers are epitaxially grown over a large area before these layers are patterned into the laterally spaced regions 3. It is also possible that the regions 3 are patterned during epitaxy. If the patterning is performed after epitaxy, the regions 3 may be defined locally at room temperature, which may compensate for expansion effects with respect to temperature change. The local exposure of the photostructurable mask can also be performed at room temperature.

Depending on the doping concentration, the doped regions 3 have predetermined optical properties and predetermined electrical properties. For example, a refractive index of the doped regions 3 can be set based on the doping concentration. In order to reduce the electrical resistance, the regions 3 may be high-doped. In order to improve the optical properties, in particular with respect to the transmission of light of a certain wavelength, the regions 3 may be formed with a low doping concentration.

After the formation of the regions 3, the photo-lithographic mask can be removed. The growth substrate 1A may be exposed in some areas. Referring to FIG. 6B, a main layer 21B of the first semiconductor layer 21 may first be deposited on the growth substrate 1A in such a manner that the main layer 21B completely covers the partial regions 3 and completely surrounds them in lateral directions. The lateral gaps between the regions 3, shown for instance in FIG. 6A, are completely filled by the main layer 21B of the first semiconductor layer 21. At a surface of the growth substrate 1A, the regions 3 may be flush with the main layer 21B. Other semiconductor layers of the main body 2, for instance the optically active zone 23 and the second semiconductor layer 22, may be epitaxially deposited on the first semiconductor layer 21 in a subsequent method step. The main body 2 is in particular part of a main body compound 2V, which can be separated into a plurality of main bodies 2 in a subsequent method step.

In particular, the subsequent method step is carried out in an aligned manner with respect to the preceding epitaxial structures, namely with respect to the doped regions 3 buried in the main body composite 2V. The main body composite 2V may comprise adjustment marks which, for example, mark the positions of the doped regions 3 or of the main bodies 2 of the to be produced components 10.

According to FIG. 6C, for example, through-vias 20 can be formed in an aligned manner with the doped regions 3. In particular, the through-vias 20 can be arranged in such a way that, in top view, they overlap with the higher-doped regions 3H and, in particular, are free of overlap with the lower-doped regions 3N. As shown schematically in FIG. 6C, the through-vias 20 end before the doped regions 3, in particular before the higher-doped regions 3H. In deviation therefrom, it is possible that the through-vias 20 extend along the vertical direction up to the higher-doped regions 3H or even into the doped higher-doped regions 3. The electrical connections can be mapped onto the epitaxial structures, in particular onto the doped regions 3. The electrical resistance within the first semiconductor layer 21 can be lowered or increased at spatially preferred locations. Thus, electrically highly conductive regions 3H and optically optimized regions 3N can be formed in a targeted manner.

Moreover, due to the presence of the higher-doped regions 3H, the current distribution around the through-vias 20 can be improved, in particular to avoid so-called current crowding effects. Moreover, the spatial separation of the optically optimized regions 3N from the optically absorbing and current injecting regions 3H allows the realization of a first semiconductor layer 21 with spatially variable refractive index. In other words, variation from the locally defined refractive index is possible. It is also possible that color centers for wavelength conversion can be selectively generated by arranging the doped regions 3. For example, color centers are selectively embedded in predetermined locations of the main body 2, which are arranged in particular aligned with the doped regions 3. Local embedding of geometric structures can also be carried out in an aligned manner with respect to the doped regions 3.

In the finished component, a correlation between the doped regions 3 and the geometry of the component 3 can be demonstrated. Correlated variations in the doping profile or electrical conductivity in the layered regions can also be detected. In particular, the spatial arrangement of the optical properties with respect to the chip structure is detectable. In operation of the component, the current paths are in particular geometrically definable.

In a subsequent method step, an auxiliary carrier may be fixed on the main body composite 2V so that the main body composite 2V is arranged in the vertical direction between the growth substrate 1A and the auxiliary carrier. The growth substrate 1A may be subsequently removed. In particular, the subcarrier serves as a carrier 1 of the main body composite 2V or the component 10.

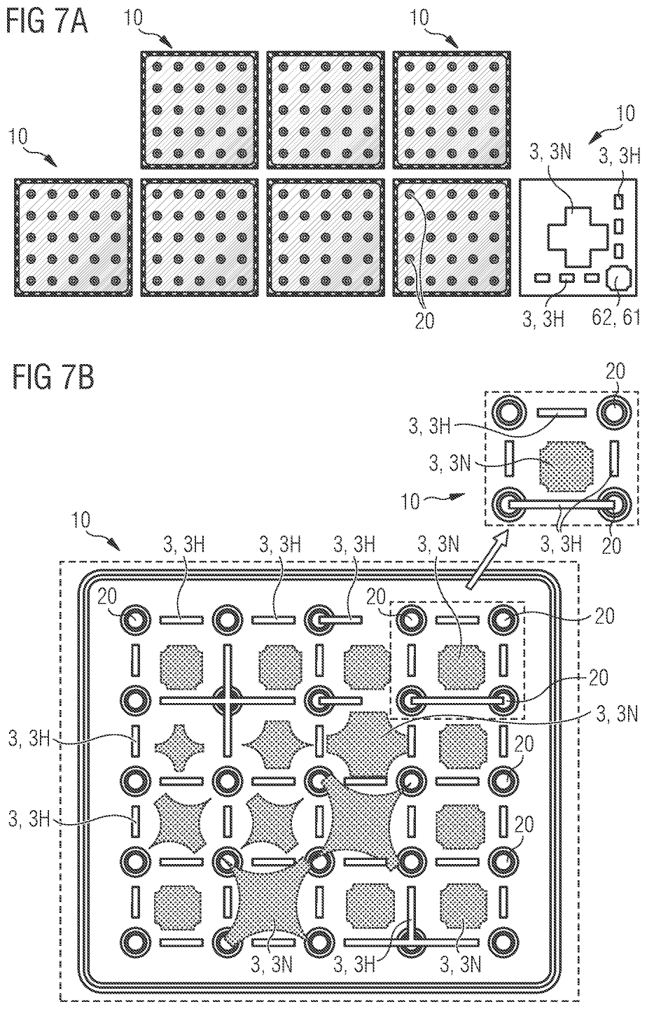

According to FIGS. 7A and 7B, the carrier 1 having the main body composite 2V disposed thereon may be singulated into a plurality of components 10. The singulated component 10 may comprise a main body 2 having doped regions 3, 3H and 3N buried therein, wherein the doped regions 3, 3H and/or 3N are adapted to the geometry of the main body 2 or to the geometry of the component 2.

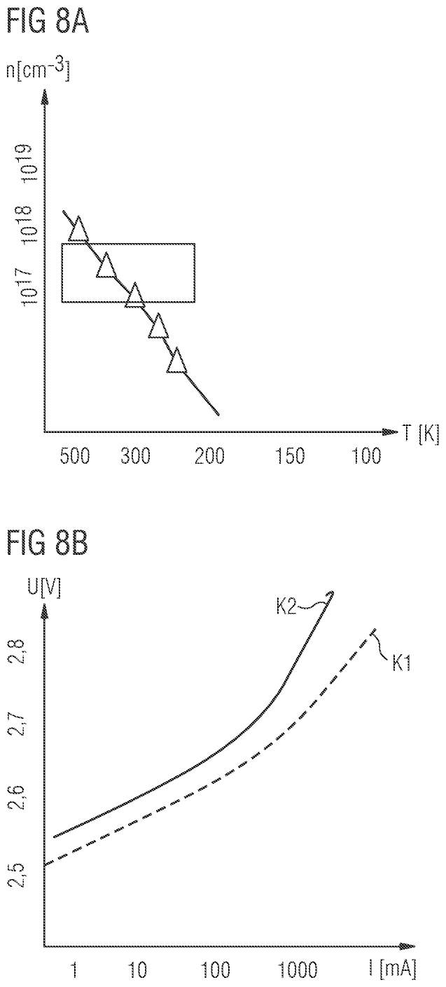

FIG. 8A schematically shows the doping concentration of a p-doped, in particular Mg-doped GaN layer. The doping concentration can be dependent on the activation energy or on the temperature T. FIG. 8B shows two curves K1 and K2, which show the variation of the voltage U as a function of the current intensity I. Curve K1 shows the voltage U and the current I in a GaN:Si layer with a doping concentration of about 1.7×10¹⁸ cm⁻³. Curve K2 shows the voltage U and the current I in a GaN:Si layer with a dopant concentration of about 5·10¹⁸ cm⁻³. Instead of Si, germanium can also be used as dopant. The dopant concentration of Si or Ge can be as low as 3-4×10¹⁹ cm⁻³. On the basis of the curves K1 and K2 a course of the electrical resistance can be derived.

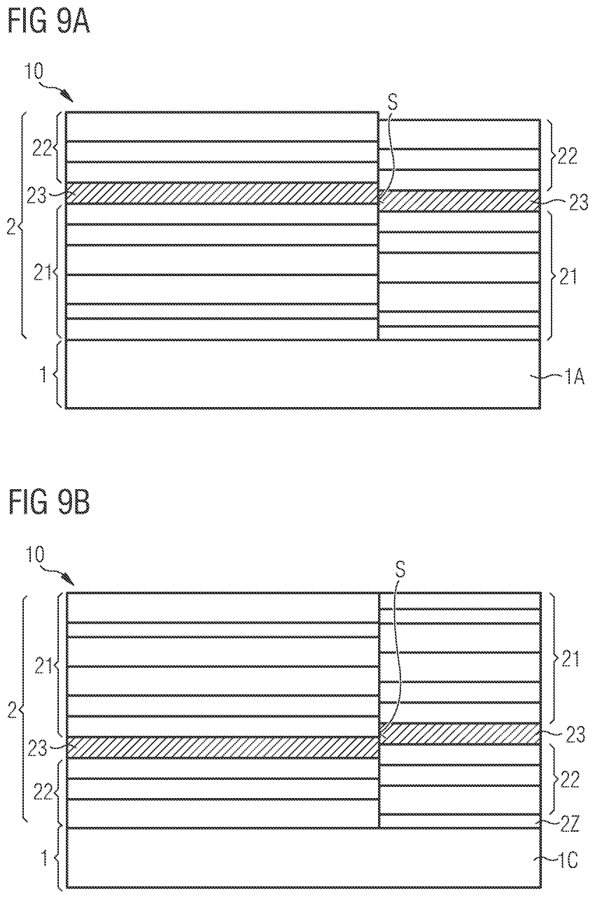

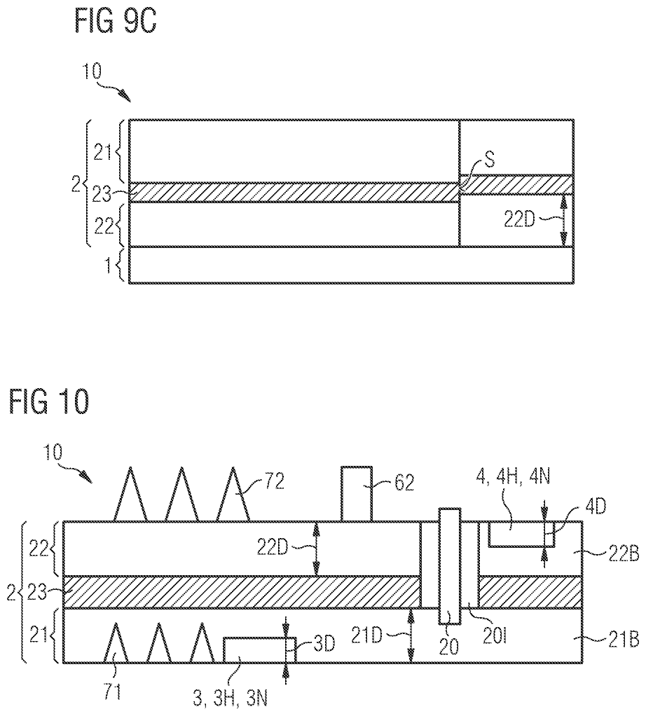

FIGS. 9A, 9B and 9C show further possible exemplary embodiments of a component 10 described herein. In FIGS. 8A and 8B, it is schematically shown that the first semiconductor layer 21 and the second semiconductor layer 22 are each implemented as a sequence of layers. For example, the first semiconductor layer 21 may include a buffer layer of for instance AlN, a adaption layer having a layer thickness of for instance 3000 nm, a GaN contact layer doped with Si, an n-type current expanding layer doped with Si, and transition layers. The second semiconductor layer 22 may comprise transition layers, a p-type Mg-doped current spreading layer and contact layers.

As shown schematically in FIGS. 9A, 9B and 9C, the active zone 23 may comprise at least two sub-regions or a plurality of sub-regions which are mechanically interconnected but vertically offset from each other. The component 10 illustrated in FIG. 9B differs from the component 10 illustrated in FIG. 9A, in particular wherein the growth substrate 1A is removed after the formation of the carrier 1 or 1C. In order to planarize a surface facing the carrier 1, the main body may include an adaption layer 2Z which is disposed in particular between the second semiconductor layer 22 and the carrier 1.

FIG. 10 shows further possible exemplary embodiments of a component 10 described herein. In particular, the component 10 may comprise inner out-coupling structures 71 and outer out-coupling structures 72. The inner out-coupling structures 71 are structures within the first semiconductor layer 21, which are formed, for example, by using a patterned growth substrate 1A. The outer out-coupling structures 72 are in particular structures formed, for example, by patterning the second semiconductor layer 22.

FIG. 10 further shows schematically that the locally doped regions 3 and 4 may be formed in both the first semiconductor layer 21 and the second semiconductor layer 22. Analogous to the locally doped regions 3 in the first semiconductor layer 21, the doped regions 4 may be at least partially buried in the second semiconductor layer 22, in particular in a main layer 22B of the second semiconductor layer 22. The regions 4 may be higher-doped or lower-doped compared to the main layer 22B. The regions 4 also have a vertical layer thickness 4D that is smaller than a vertical layer thickness 22D of the second semiconductor layer 22.

The invention is not restricted to the exemplary embodiments by the description of the invention made with reference to the exemplary embodiments. The invention rather comprises any novel feature and any combination of features, including in particular any combination of features in the claims, even if this feature or this combination is not itself explicitly indicated in the patent claims or exemplary embodiments.

1.-18. (canceled)

19. A component comprising:
a carrier; and
a main body disposed on the carrier,
wherein the main body comprises a first semiconductor layer of a first charge carrier type, a second semiconductor layer of a second charge carrier type, and an optically active zone located therebetween, the optically active zone configured to emit radiation,
wherein the first semiconductor layer comprises a contiguous main layer and local regions at least locally buried in the main layer and laterally enclosed by the main layer,
wherein the local regions are doped, and
wherein the local regions has a smaller vertical layer thickness compared to the first semiconductor layer.

20. The component according to claim 19, wherein the local regions are individual laterally spaced regions of the first semiconductor layer, and wherein the main layer is disposed in a vertical direction at least partially between the active zone and the local regions.

21. The component according to claim 19, wherein the local regions and the main layer are based on the same semiconductor material, the main layer having a greater maximum vertical layer thickness than the local regions.

22. The component according to claim 19, wherein the main layer has a first doping concentration and the local regions have a doping concentration differing by at least 5% from the first doping concentration.

23. The component according to claim 19, wherein the first semiconductor layer is n-type, wherein the main layer has a maximum dopant concentration between 4·10¹⁸ cm⁻³ and 4·10¹⁹ cm⁻³ inclusive, wherein the local regions are implemented in places as current distribution bridges having a lower electrical resistance than the main layer, and wherein a doping concentration of the current distribution bridges is at least 5% greater than a doping concentration of the main layer.

24. The component according to claim 19, wherein the first semiconductor layer is n-type, wherein the main layer has a maximum dopant concentration between 4·10¹⁸ cm⁻³ and 4·10¹⁹ cm⁻³ inclusive, wherein the local regions are implemented in places as optically favored windows having a greater transmittance than the main layer for the radiation, and wherein the optically favored windows have a doping concentration which is at least 5% smaller than a doping concentration of the main layer.

25. The component according to claim 19, wherein the first semiconductor layer is p-type, wherein the main layer has a maximum doping concentration of between 1·10¹⁷ cm⁻³ and 3·10¹⁸ cm⁻³ inclusive, wherein the local regions are implemented in places as current distribution bridges having a lower electrical resistance than the main layer, and wherein a doping concentration of the current distribution bridges is at least 5% greater than a doping concentration of the main layer.

26. The component according to claim 19, wherein the first semiconductor layer is p-type, wherein the main layer has a maximum doping concentration of between 1·10¹⁷ cm⁻³ and 3·10¹⁸ cm⁻³ inclusive, wherein the local regions are implemented in places as optically favored windows which have a greater transmittance than the main layer for the radiation, and wherein the optically favored windows have a doping concentration which is at least 5% smaller than the doping concentration of the main layer.

27. The component according to claim 19, wherein the local regions are formed in places as current distribution bridges and in places as optically favored windows, the current distribution bridges having a higher doping concentration than the optically favored windows.

28. The component according to claim 19, wherein the second semiconductor layer comprises a contiguous main layer and local regions, wherein the local regions are buried at least in places in the main layer of the second semiconductor layer and are laterally enclosed by the main layer of the second semiconductor layer, wherein the local regions are doped, and wherein the local regions have a smaller vertical layer thickness compared to the second semiconductor layer.

29. The component according to claim 19, wherein the component has a plurality of laterally spaced through-vias, wherein the through-vias extend throughout the second semiconductor layer and the active zone into the first semiconductor layer in order to provide electrically contacting for the first semiconductor layer, and wherein, in top view of the carrier, at least some of the through-vias overlap with the local regions formed as current distribution bridges.

30. The component according to claim 19, wherein the component has a plurality of laterally spaced through-vias, wherein the through-vias extend throughout the second semiconductor layer and the active zone into the first semiconductor layer in order to provide electrically contacting for the first semiconductor layer, and wherein, in top view of the carrier, the through-vias and the local regions formed as optically favored windows are free of overlaps.

31. The component according to claim 19, wherein the component comprises a contact point for externally electrically contacting the component, wherein the local regions are formed in areas as current distribution bridges, and the current distribution bridges have a gradient with respect to their doping concentration so that the current distribution bridges having a first lateral distance from the contact point have a higher doping concentration than the current distribution bridges having a second lateral distance from the contact point, and wherein the first distance is smaller than the second distance.

32. The component according to claim 19, wherein the optically active zone has an internal vertical step in the main body, and wherein each of the first semiconductor layer and the second semiconductor layer has a corresponding vertical jump at the step of the active zone.

33. The component according to claim 19, further comprising out-coupling structures configured to increase an out-coupling efficiency of the radiation, and wherein the out-coupling structures are located in places on the main body and/or within the main body.

34. A light source comprising:
the component according to claim 19,
wherein the optically active zone is configured to generate the radiation in a visible, an infrared or an ultraviolet spectral range.

35. A method for producing a component having a main body comprising a first semiconductor layer of a first carrier type, a second semiconductor layer of a second carrier type, and an optically active zone located therebetween, the method comprising:
forming a plurality of laterally spaced and doped regions from a semiconductor material on a growth substrate; and
overgrowing the doped regions with semiconductor materials to form the main body in such that the doped regions are formed as integral subregions of the first semiconductor layer,
wherein the first semiconductor layer comprises a contiguous main layer,
wherein the doped regions are at least locally buried in the main layer and laterally enclosed by the main layer,
wherein the doped regions adjust local electrical and local optical properties of the first semiconductor layer, and
wherein the local regions have a smaller vertical layer thickness compared to the first semiconductor layer.

36. The method according to claim 35, further comprising forming a plurality of laterally spaced through-vias, the through-vias for electrically contacting the first semiconductor layer in such that the through-vias extend throughout the second semiconductor layer and the active zone into the first semiconductor layer, and the through-vias are formed in an aligned manner with respect to local buried doped regions.
